(19) United States
(12) Patent Application Publication
(10) Pub. No.: US 2013/0265062 A1
(43) Pub. Date: Oct. 10, 2013

(54) CAPACITIVE TOUCH KEY AND THE OPERATING METHOD THEREOF

(71) Applicants: CHI-HAO WANG, Hsinchu (TW); CHIA-MING CHANG, Hsinchu County (TW)

(72) Inventors: CHI-HAO WANG, Hsinchu (TW); CHIA-MING CHANG, Hsinchu County (TW)

(21) Appl. No.: 13/794,833

(22) Filed: Mar. 12, 2013

(30) Foreign Application Priority Data
Apr. 5, 2012 (TW) 101111993

(51) Int. Cl. G01R 27/26

(52) U.S. Cl. CPC G01R 27/2605
USPC 324/686

(57) ABSTRACT

A capacitive touch key is disclosed. The capacitive touch key includes a capacitive key, generating a first capacitance value when a user is close to the capacitive key; a mechanical key connected with the capacitive key; a capacitor connected with the mechanical key and having a second capacitance value; and a processing unit connected with the capacitive key, wherein the processing unit detects the first capacitance value when the mechanical key is not pressed by a user, and the processing unit detects the first capacitance value and the second capacitance value when the mechanical key is pressed by a user.

### CROSS REFERENCE TO RELATED APPLICATIONS

This application claims the benefit of priority of TAIWAN Patent Application No. 101111993, filed Apr. 5, 2012, which is incorporated by reference herein in their entirety.

### BACKGROUND OF THE INVENTION

1. Field of the Invention

The present invention relates to a capacitive touch key and the operating method thereof. More particularly, the present invention relates to a capacitive touch key accompanying a mechanical key and the operating method thereof

2. Description of Related Art

For a general capacitive touch key, when a finger of a user is close to or touches the capacitive touch key, the capacitance value will be changed so that the system can determine that the user has pressed the key. However, when the user is close to or touches the capacitive touch key, there is no sensation of pressing a key when, in fact, the key has already been pressed.

In view of this, some systems can provide a feedback mechanism. For example, when the key is pressed, the system will emit a bright light or provide vibration to inform the user that the key has been pressed.

The capacitive touch key has become increasingly popular in all kinds of electronic-applied products, such as televisions, refrigerators, washers, and so on. Due to the different appearance designs of various kinds of electronic-applied products, sometimes key regions must be located at places which are not as noticeable (e.g., the rear of the television). In such a situation, the user has to touch the right location for the feedback mechanism to occur. However, the user has to search for the key region on the flat glass before being able to touch the right location of the key. It is inconvenient, and it is also possible to touch the key mistakenly when searching for the key region.

### SUMMARY OF THE INVENTION

One objective of the present invention discloses a capacitive touch key comprising: a capacitive key, generating a first capacitance value when a user is close to the capacitive key; a mechanical key, connected with the capacitive key; a capacitor, connected with the mechanical key and having a second capacitance value; and a processing unit, connected with the capacitive key, wherein the processing unit detects the first capacitance value when the mechanical key is not pressed by the user, and the processing unit detects the first capacitance value and the second capacitance value when the mechanical key is pressed by the user.

Another objective of the present invention discloses a method of operating a capacitive touch key which comprises a capacitive key and a mechanical key. The method comprises the following steps: detect the variance of a first capacitance value generated when a user is close to the capacitive key; provide a first reaction; detect the variance of a second capacitance value generated when the user presses the mechanical key; and provide a second reaction.

Another objective of the present invention discloses a method of operating an electronic product having a plurality of capacitive touch keys, wherein each of the plurality of capacitive touch keys comprises a capacitive key and a mechanical key. The method comprises the following steps: detect the variance of a first capacitance value generated when a user is close to a first capacitive key of the plurality of capacitive touch keys; provide a first reaction; detect the variance of a second capacitance value generated when a user presses a first mechanical key corresponding to the first capacitive key; and provide a second reaction.

### BRIEF DESCRIPTION OF THE DRAWINGS

FIG. 1 illustrates a capacitive touch key in the first embodiment of the present invention;

FIG. 2 illustrates the method of operating the capacitive touch key in the second embodiment of the present invention; and

FIG. 3 illustrates the method of operating the electronic product to which the capacitive touch key is applied.

### DESCRIPTION OF EMBODIMENTS

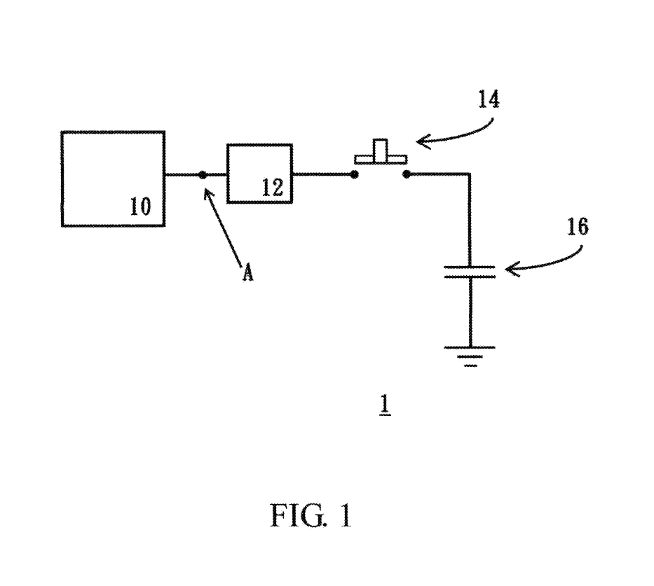

Please refer to FIG. 1, which illustrates a capacitive touch key 1 in the first embodiment of the present invention. A capacitive touch key comprises a processing unit 10, a capacitive key 12, a mechanical key 14 and a capacitor 16. The capacitive key 12 is physically structured as an electrode formed by copper foil. There is a capacitor (not shown) on a scan line, or between a plurality of scan lines, with a capacitance value denoted by C1. When a finger of a user or a conductor is close to the capacitive key 12, the capacitance value C1 on the scan line, or a capacitor between the plurality of scan lines, is changed. For example, when a finger of a user or a conductor is not close to the capacitive key 12, the capacitance value C1 is 0.1 p; and when a finger of a user or a conductor is close to the capacitive key 12, the capacitance value C1 increases to 0.2 p. A mechanical key 14 is connected to the capacitive key 12. The mechanical key 14 can function as a switch. When the mechanical key 14 is pressed by a finger of a user, the switch will close; when the mechanical key 14 is not pressed by a finger of a user, the switch will open. The capacitor 16 is connected with the mechanical key 14. The capacitance value of the capacitor 16 is denoted by C2. For example, the capacitance value C2 can be 2 p. When the switch closes, the capacitance value C1 and the capacitance value C2 are connected in parallel; and when the switch opens, the capacitance value C1 and the capacitance value C2 are separated. A processing unit 10 is connected with the capacitive key 12 to detect the capacitance value of the node A.

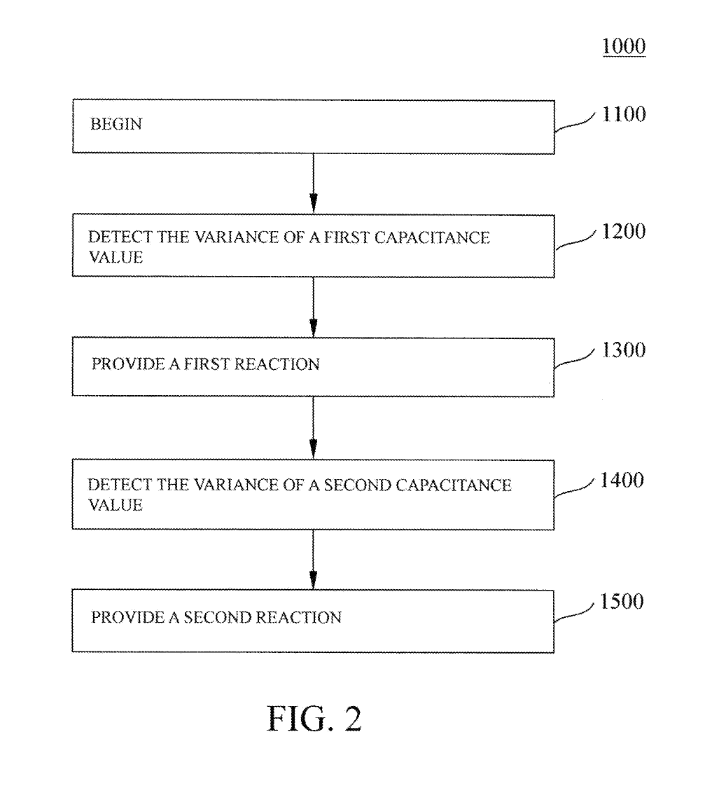

Please refer to FIG. 2 along with FIG. 1. FIG. 2 illustrates the method 1000 of operating the capacitive touch key 1 in the second embodiment of the present invention. The method 1000 of operating the capacitive touch key 1 comprises the following steps. In step 1100, flow process begins. In step 1200, the processing unit 10 detects the variance of a first capacitance value which comes from the sensed capacitance value C1 generated when a user is close to the capacitive key 12. If C1 exceeds a predefined critical value, a first reaction is provided in step 1300. Then, in step 1400, the processing unit 10 detects the variance of a second capacitance value generated when a user presses the mechanical key 14. When the mechanical key 14 is pressed by a user and the switch closes, the capacitance value C2 of the capacitor 16 can be detected by the processing unit 10, and the capacitance value of the node A can be detected as a combination of the capacitance value C1 and the capacitance value C2. In this embodiment, the capacitance value C2 is larger than the capacitance value C1 in design so that the processing unit 10 can easily determine whether a user is close to the capacitive key 12 or has pressed the mechanical key 14. Finally, when the processing unit 10 determines that the mechanical key 14 has been pressed, a second reaction is provided in step 1500.

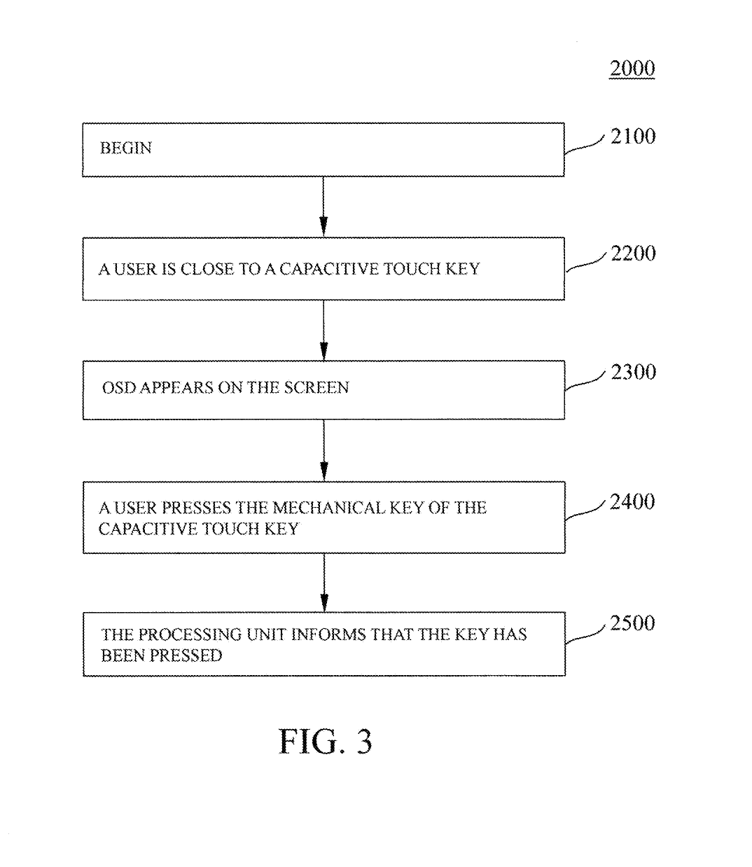

Please refer to FIG. 3 along with FIG. 1. FIG. 3 illustrates the method 2000 of operating the electronic product to which the capacitive touch key 1 is applied. The electronic product comprises a screen and a plurality of capacitive touch keys, wherein each of the plurality of capacitive touch keys is the same as the capacitive touch key used in the first embodiment. In other words, each of a plurality of capacitive touch keys comprises a capacitive key and a mechanical key. For example, the effects of pressing a plurality of mechanical keys includes increasing screen brightness, decreasing screen brightness, powering on or off the electronic product, and so on. The method 2000 of operating the electronic product to which the capacitive touch key 1 is applied comprises the following steps. In step 2000, flow process begins. In step 2200, the processing unit 10 detects the sensed capacitance value C1 of the capacitive key 12 of the capacitive touch key 1 when a user is close to a capacitive key 12 of the plurality of capacitive touch keys 1, wherein if the capacitance value C1 exceeds a predefined critical value, an on-screen-display (abbreviated as OSD) will appear on the screen of the electronic product to inform the user of the location and functional definition of the mechanical key 14 at which the user points his finger in step 2300. For example, the mechanical key at which the user points his finger is a key that increases screen brightness. Then, in step 2400, when a user presses the mechanical key 14 and the switch closes, the capacitance value C2 of the capacitor 16 of the mechanical key 14, which increases screen brightness, can be detected by the processing unit 10. That is, the capacitance value of the node A can be detected as a combination of the capacitance value C1 and the capacitance value C2. For example, the C1 and C2 are connected in parallel. Then, in step 2500, the processing unit 10 informs the electronic product that the user has pressed the key that increases screen brightness so that the electronic product can increase the screen brightness.

The above disclosures are merely exemplary embodiments of the present invention, and the present invention is not limited to the details of the above embodiments. The protective scope of the present invention is merely limited to the following claims.

What is claimed is:

1. A capacitive touch key, comprising:
a capacitive key, generating a first capacitance value when a user is close to the capacitive key;
a mechanical key, connected with the capacitive key;
a capacitor, connected with the mechanical key and having a second capacitance value; and
a processing unit, connected with the capacitive key,
wherein the processing unit detects the first capacitance value when the mechanical key is not pressed by the user, and the processing unit detects the first capacitance value and the second capacitance value when the mechanical key is pressed by the user.

2. The capacitive touch key according to claim 1, wherein the second capacitance value is larger than the first capacitance value.

3. The capacitive touch key according to claim 1, wherein when the mechanical key is pressed by the user, the mechanical key detects that the first capacitance value and the second capacitance value are connected in parallel.

4. A method of operating a capacitive touch key, wherein the capacitive touch key comprises a capacitive key and a mechanical key, the method comprising the steps of:
detecting the variance of a first capacitance value generated when a user is close to the capacitive key;
providing a first reaction;
detecting the variance of a second capacitance value generated when the user presses the mechanical key; and
providing a second reaction.

5. The method of operating a capacitive touch key according to claim 4, wherein the variance of the second capacitance value is larger than that of the first capacitance value.

6. The method of operating a capacitive touch key according to claim 4, wherein the first reaction informs the user of the following information:
the location of the mechanical key; and
functional definition of the mechanical key.

7. A method of operating an electronic product having a plurality of capacitive touch keys, wherein each of the plurality of capacitive touch keys comprises a capacitive key and a mechanical key, the method comprising the steps of:
detecting the variance of a first capacitance value generated when a user is close to a first capacitive key of the plurality of capacitive touch keys;
providing a first reaction;
detecting the variance of a second capacitance value generated when a user presses a first mechanical key corresponding to the first capacitive key; and
providing a second reaction.

8. The method of operating an electronic product according to claim 7, wherein the variance of the second capacitance value is larger than that of the first capacitance value.

9. The method of operating an electronic product according to claim 7, wherein the first reaction informs the user of the following information:
the location of the mechanical key; and
functional definition of the mechanical key.
